(19) United States
(12) Patent Application Publication
(10) Pub. No.: US 2025/0183233 A1
(43) Pub. Date: Jun. 5, 2025

(54) POWER MODULE SEMICONDUCTOR PACKAGE AND SEMICONDUCTOR APPARATUS

(71) Applicant: Mitsubishi Electric Corporation, Tokyo (JP)

(72) Inventors: Kozo HARADA, Chiyoda-ku, Tokyo (JP); Hodaka ROKUBUICHI, Chiyoda-ku, Tokyo (JP)

(73) Assignee: Mitsubishi Electric Corporation, Tokyo (JP)

(21) Appl. No.: 18/835,024

(22) PCT Filed: Mar. 14, 2022
(86) PCT No.: PCT/JP2022/011345

§ 371 Date: Aug. 1, 2024

(51) Int. Cl. H01L 25/07; H01L 23/00; H01L 23/31; H01L 23/373; H01L 23/538

(52) U.S. Cl. CPC H01L 25/074; H01L 23/5384; H01L 24/32; H01L 24/48; H01L 24/73; H01L 23/3107; H01L 23/3736; H01L 2224/32225; H01L 2224/48106; H01L 2224/48111; H01L 2224/48155; H01L 2224/48225; H01L 2224/73265; H01L 2225/0651; H01L 2225/06589

(57) ABSTRACT

A power module semiconductor package comprises a substrate, a first power semiconductor device, a second power semiconductor device, a heat spreader, a sealing resin, and the like. In a plan view seen from a second major surface of the substrate, the first power semiconductor device includes a region that does not overlap with the second power semiconductor device and the substrate. The non-overlapping region is located at a substrate opening of the substrate. A first signal electrode of the first power semiconductor device and a first signal terminal are electrically connected to each other by a first bonding wire through the substrate opening.

### TECHNICAL FIELD

The present disclosure relates to a power module semiconductor package and a semiconductor apparatus.

### BACKGROUND ART

A semiconductor device of a type having a conduction path in a vertical direction of the semiconductor device in order to accommodate a high voltage and a large current, is generally referred to as a power semiconductor device. Examples of the power semiconductor device include an insulated gate bipolar transistor (IGBT), a MOS field effect transistor (MOSFET: metal oxide semiconductor field effect transistor), a bipolar transistor, and a diode.

There is a power module semiconductor package in which a power semiconductor device is mounted on a circuit board and packaged with a sealing resin. Such a power module semiconductor package is connected to a cooler referred to as a heat sink, a control component, and the like, and used as a semiconductor apparatus (or power conversion equipment) in a wide range of fields such as industrial equipment, automobiles, railroads, and the like.

In recent years, as equipment with a semiconductor apparatus (or power conversion equipment) mounted therein is reduced in size and weight, there also is a demand for a power module semiconductor package reduced in size and weight. A known structure of a power module semiconductor package is a transfer molded semiconductor package having sealing resin molded in a transfer molding method. The transfer molded semiconductor package is vigorously developed as it has high productivity and high reliability.

In order to ensure heat dissipation, a transfer molded semiconductor package has a power semiconductor device mounted on a heat spreader that is a metal member. The power semiconductor device has an electrode electrically connected by a bonding wire to a lead frame used as an external terminal. Further, an end portion of the lead frame serving as an external connection terminal projects from the sealing resin. Further, in order to ensure heat dissipation, the heat spreader has a bottom surface (a front surface) exposed at a surface of the sealing resin.

The transfer molded semiconductor package further has a heat sink joined to the exposed heat spreader in order to ensure heat dissipation in an actual operation. The heat sink is in the form of a fin. The heat spreader and the heat sink are joined together by a heat-dissipative and insulating layer. The transfer molded semiconductor package with the heat sink attached thereto is often used as a semiconductor apparatus (or power conversion equipment).

Power module semiconductor packages are disclosed for example in patent literature PTLs 1, 2 and 3.

### CITATION LIST

### Patent Literature

PTL 1: Japanese Patent Laying-Open No. 2011-258594
PTL 2: Japanese Patent Laying-Open No. 2013-110181
PTL 3: Japanese Patent Laying-Open No. 2015-070269

### SUMMARY OF INVENTION

### Technical Problem

As has been set forth above, as equipment with a semiconductor apparatus (or power conversion equipment) mounted therein is reduced in size and weight, there also is a demand for a power module semiconductor package reduced in size and the like.

The present disclosure has been made under such development, and one object thereof is to provide a power module semiconductor package capable of achieving miniaturization, and another object thereof is to provide a semiconductor apparatus as power conversion equipment with such a power module semiconductor package applied thereto.

### Solution to Problem

A power module semiconductor package according to the present disclosure comprises a substrate, a first power semiconductor device, a second power semiconductor device, an external main terminal, a signal terminal, and a sealing resin. The substrate has a first major surface and a second major surface opposite to each other. The first power semiconductor device is mounted on the substrate at the first major surface. The second power semiconductor device is mounted on the substrate at the second major surface. The external main terminal includes a first external main terminal electrically connected to the first power semiconductor device and a second external main terminal electrically connected to the second power semiconductor device. The signal terminal includes a first signal terminal electrically connected to the first power semiconductor device and a second signal terminal electrically connected to the second power semiconductor device. The sealing resin seals the first power semiconductor device and the second power semiconductor device in such a manner that the external main terminal and the signal terminal protrude. The external main terminal is disposed on a side opposite to a side on which the signal terminal is disposed with respect to the first power semiconductor device and the second power semiconductor device. The first power semiconductor device and the second power semiconductor device are electrically connected to each other via a via penetrating the substrate. In a plan view seen from the second major surface of the substrate, the first power semiconductor device includes a region that does not overlap with the second power semiconductor device and the substrate. The first power semiconductor device and the first signal terminal are electrically connected to each other by a bonding wire that interconnects the non-overlapping region of the first power semiconductor device and the first signal terminal.

A semiconductor apparatus according to the present disclosure is a semiconductor apparatus having the above-described power module semiconductor package, and comprises a cooler, a main conversion circuit, and a control circuit. The cooler is attached to the power module semiconductor package. The main conversion circuit receives power, converts the received power, and outputs the converted power. The control circuit outputs a control signal to the main conversion circuit to control the main conversion circuit.

### Advantageous Effects of Invention

The presently disclosed power module semiconductor package comprises the first power semiconductor device that has a region that does not overlap with the second power semiconductor device and the substrate in a plan view seen from the second major surface of the substrate. The first power semiconductor device and the first signal terminal are electrically connected to each other by a bonding wire that interconnects the non-overlapping region of the first power semiconductor device and the first signal terminal. This can achieve reduction in size and weight.

The presently disclosed semiconductor apparatus has a cooler attached to the above-described power module semiconductor package. This allows the semiconductor apparatus to be reduced in size and weight.

### BRIEF DESCRIPTION OF DRAWINGS

FIG. 1 is a plan view showing a structure of a power module semiconductor package according to a first embodiment.

FIG. 2 is a cross section taken along a cross-sectional line II-II shown in FIG. 1 in the same embodiment.

FIG. 3 is another plan view showing the structure of the power module semiconductor package in the same embodiment.

FIG. 4 is a cross section showing a step of a method for manufacturing the power module semiconductor package in the same embodiment.

FIG. 5 is a cross section showing a step performed after the step shown in FIG. 4 in the same embodiment.

FIG. 6 is a cross section showing a step performed after the step shown in FIG. 5 in the same embodiment.

FIG. 7 is a cross section showing a step performed after the step shown in FIG. 6 in the same embodiment.

FIG. 8 is a cross section showing a step performed after the step shown in FIG. 7 in the same embodiment.

FIG. 9 is a plan view showing a structure of a power module semiconductor package according to a first comparative example.

FIG. 10 is a cross section taken along a cross-sectional line X-X shown in FIG. 9.

FIG. 11 is a cross section showing a structure of a power module semiconductor package according to a second comparative example.

FIG. 12 is a plan view showing a structure of a power module semiconductor package according to a second embodiment.

FIG. 13 is a cross section taken along a cross-sectional line XIII-XIII shown in FIG. 12 in the same embodiment.

FIG. 14 is another plan view showing the structure of the power module semiconductor package in the same embodiment.

FIG. 15 is a cross section showing a step of a method for manufacturing the power module semiconductor package in the same embodiment.

FIG. 16 is a cross section showing a step performed after the step shown in FIG. 15 in the same embodiment.

FIG. 17 is a cross section showing a step performed after the step shown in FIG. 16 in the same embodiment.

FIG. 18 is a cross section showing a step performed after the step shown in FIG. 17 in the same embodiment.

FIG. 19 is a cross section showing a step performed after the step shown in FIG. 18 in the same embodiment.

FIG. 20 is a cross section showing a structure of a power module semiconductor package according to a third embodiment.

FIG. 21 is a cross section showing a structure of a power module semiconductor package according to a fourth embodiment.

FIG. 22 is a cross section showing a structure of a power module semiconductor package according to a fifth embodiment.

FIG. 23 is a cross section showing a structure of a power module semiconductor package according to a sixth embodiment.

FIG. 24 is a cross section showing a structure of a first example of a semiconductor apparatus according to a seventh embodiment.

FIG. 25 is a cross section showing a structure of a second example of the semiconductor apparatus in the same embodiment.

FIG. 26 is a block diagram of a semiconductor apparatus according to an eighth embodiment.

### DESCRIPTION OF EMBODIMENTS

Note that, throughout the present specification, a power semiconductor device sealed with molding resin is referred to as a power module semiconductor package. The power module semiconductor package with a cooler such as a heat sink attached thereto is referred to as a semiconductor apparatus as power conversion equipment.

Furthermore, in each embodiment, a power module semiconductor package and the like will be described using an X-Y-Z coordinate axes (three-dimensional coordinate axes), as necessary.

### First Embodiment

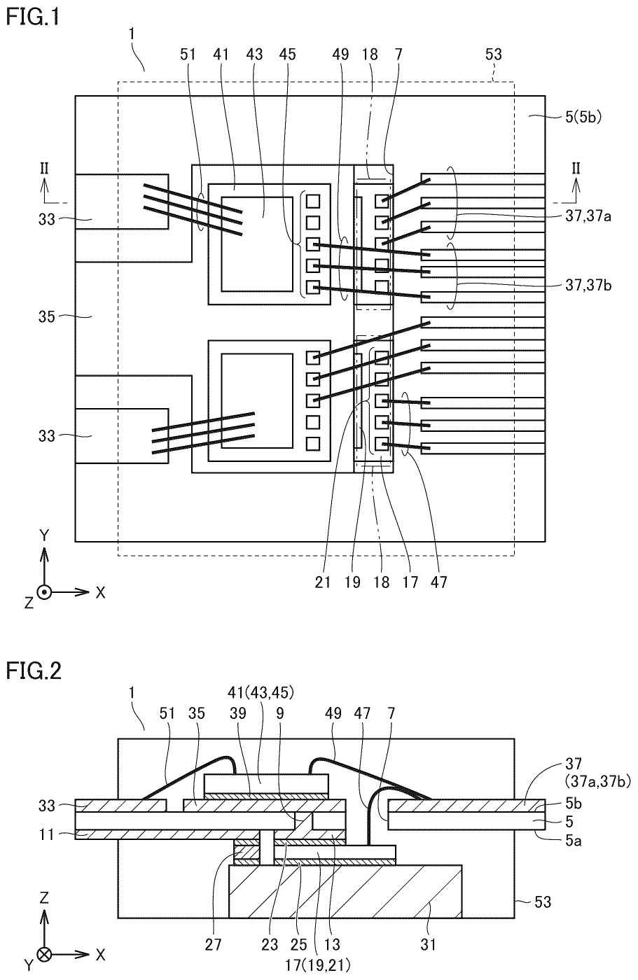

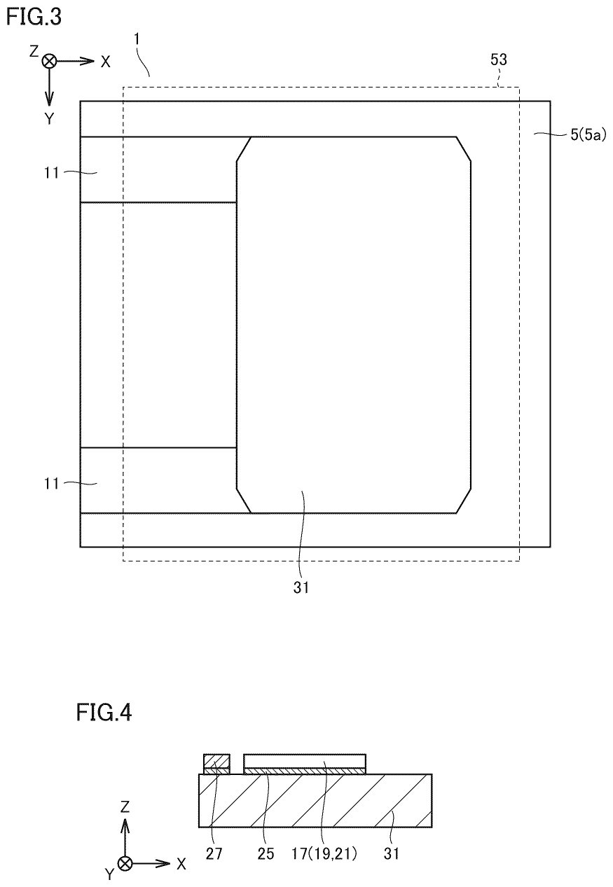

An example of a power module semiconductor package according to a first embodiment will be described. As illustrated in FIGS. 1, 2, and 3, a power module semiconductor package 1 according to the first embodiment comprises a substrate 5, a first power semiconductor device 17, a second power semiconductor device 41, a heat spreader 31, a metal block 27, a first bonding wire 47, a second bonding wire 49, a third bonding wire 51, a scaling resin 53, and the like.

Substrate 5 has a first major surface 5a and a second major surface 5b opposite to each other. A first interconnection layer 13 and a first external main terminal 11 are formed on first major surface 5a of substrate 5. A second interconnection layer 35, a second external main terminal 33, and a signal terminal 37 are formed on second major surface 5b of substrate 5. First interconnection layer 13 and second interconnection layer 35 are electrically connected to each other by a via 9 penetrating substrate 5. Signal terminal 37 includes a first signal terminal 37a and a second signal terminal 37b. Substrate 5 has a substrate opening 7 formed to penetrate through substrate 5.

A first main electrode 19 and a first signal electrode 21 are formed at first power semiconductor device 17. A second main electrode 43 and a second signal electrode 45 are formed at second power semiconductor device 41. First main electrode 19 for first power semiconductor device 17 is bonded to first interconnection layer 13 by solder 23. Metal block 27 is bonded to first external main terminal 11 by solder 23.

Heat spreader 31 is bonded by solder 25 on a side opposite, with respect to first power semiconductor device 17 and metal block 27, to a side on which substrate 5 is bonded. Second power semiconductor device 41 is bonded to second interconnection layer 35 by solder 39.

In a plan view seen from second major surface 5b of substrate 5 (i.e., an X-Y plane), first power semiconductor device 17 includes a region 18 (an offset region) that does not overlap with second power semiconductor device 41 and substrate 5, and region 18 that does not overlap is located at substrate opening 7 of substrate 5. First signal electrode 21 of first power semiconductor device 17 and first signal terminal 37a are electrically connected to each other by first bonding wire 47 through substrate opening 7.

Second signal electrode 45 of second power semiconductor device 41 and second signal terminal 37b are electrically connected to each other by second bonding wire 49. Second main electrode 43 of second power semiconductor device 41 and second external main terminal 33 are electrically connected to each other by third bonding wire 51.

Sealing resin 53 is formed to seal first power semiconductor device 17, second power semiconductor device 41, and the like in such a manner that first external main terminal 11, second external main terminal 33, and signal terminal 37 protrude and heat spreader 31 has a front surface (or a bottom surface) exposed.

Power module semiconductor package 1 will be supplementarily described. As first power semiconductor device 17 and second power semiconductor device 41, a power controlling semiconductor device such as an insulated gate bipolar transistor (IGBT) or a MOS field effect transistor (MOSFET), a freewheeling diode, or the like is applied.

Heat spreader 31 is formed for example of an excellently heat-dissipative metal such as copper or aluminum. While first power semiconductor device 17 is bonded to heat spreader 31 by solder 25, the bonding material is not limited to solder 25, and for example, sintered silver or a conductive adhesive may be used, or a liquid phase diffusion bonding technique may be used for bonding.

Metal block 27 is formed for example of a conductive metal such as copper or aluminum. Metal block 27 has substantially the same thickness as that of first power semiconductor device 17 (along the Z-axis). While metal block 27 is bonded to heat spreader 31 by solder 25, the metal block may be bonded using sintered silver or a conductive adhesive, or using a liquid phase diffusion bonding technique. Metal block 27 electrically interconnects heat spreader 31 and first external main terminal 11 to have a function of guiding a current that passes from first power semiconductor device 17 to heat spreader 31 to first external main terminal 11.

Insofar as heat spreader 31 and first external main terminal 11 can be electrically interconnected, metal block 27 is not exclusive, and, for example, a solder ball, a metal ball or the like may be used. Furthermore, as heat spreader 31, a heat spreader provided with a protrusion in advance by forging may be used.

Herein, substrate 5 is assumed to be a glass epoxy-based organic insulating substrate. As substrate 5 may be applied an insulating film with a polymer material such as liquid crystal polymer or polyimide applied thereto. Furthermore, a ceramic or similarly inorganic insulating substrate may be used as substrate 5.

First interconnection layer 13 and first external main terminal 11 formed on first major surface 5a of substrate 5 are formed, for example, by patterning a copper or similar metal layer by etching. Second interconnection layer 35 and second external main terminal 33 formed on second major surface 5b of substrate 5 are also formed by patterning a copper or similar metal layer by etching.

First main electrode 19 of first power semiconductor device 17 is bonded to first interconnection layer 13 by solder 23. Metal block 27 is bonded to first external main terminal 11 by solder 23. The bonding material is not limited to solder 23, and for example, sintered silver or a conductive adhesive may be used, or a liquid phase diffusion bonding technique may be used bonding.

Second power semiconductor device 41 is bonded (on its back surface side) to second interconnection layer 35 by solder 39. The bonding material is not limited to solder 39, and for example, sintered silver or a conductive adhesive may be used, or a liquid phase diffusion bonding technique may be used bonding. First main electrode 19 of first power semiconductor device 17 and second power semiconductor device 41 (on its back surface) are electrically connected via first interconnection layer 13, via 9, and second interconnection layer 35.

First bonding wire 47 electrically connecting first signal electrode 21 of first power semiconductor device 17 and first signal terminal 37a is provided so as to pass through substrate opening 7. Second bonding wire 49 electrically connecting second signal electrode 45 of second power semiconductor device 41 and second signal terminal 37b is provided so as to straddle substrate opening 7. Third bonding wire 51 electrically connecting second main electrode 43 of second power semiconductor device 41 and second external main terminal 33 is provided on a side opposite to a side on which substrate opening 7 is located with respect to second power semiconductor device 41 (i.e., a negative direction along the X-axis). Power module semiconductor package 1 according to the first embodiment is configured as described above.

How a current flows through power module semiconductor package 1 will now be described. Initially, power module semiconductor package 1 externally receives a current at second external main terminal 33. The current received at second external main terminal 33 flows through third bonding wire 51 into second main electrode 43 of second power semiconductor device 41.

The current flowing into second main electrode 43 flows from the back surface of second power semiconductor device 41 and passes through second interconnection layer 35, and flows through via 9 and first interconnection layer 13 into first main electrode 19 of first power semiconductor device 17. The current flowing into first main electrode 19 is output from the back surface of first power semiconductor device 17 through heat spreader 31, metal block 27, and first external main terminal 11 externally of power module semiconductor package 1.

Meanwhile, a signal current is output from first signal electrode 21 of first power semiconductor device 17 to first signal terminal 37a via first bonding wire 47. Furthermore, a signal current is output from second signal electrode 45 of second power semiconductor device 41 to second signal terminal 37b via second bonding wire 49.

An example of a method for manufacturing power module semiconductor package 1 described above will now be briefly described.

Initially, as shown in FIG. 4, first power semiconductor device 17 and metal block 27 are bonded to a surface of heat spreader 31 by solder 25. Subsequently, substrate 5 having first major surface 5a and second major surface 5b opposite to each other is prepared (see FIG. 5). First interconnection layer 13 and first external main terminal 11 are formed on first major surface 5a of substrate 5 in advance. Furthermore, second interconnection layer 35, second external main terminal 33, and signal terminal 37 are formed on second major surface 5b of substrate 5 in advance. Furthermore, substrate opening 7 is formed in substrate 5 so as to penetrate substrate 5.

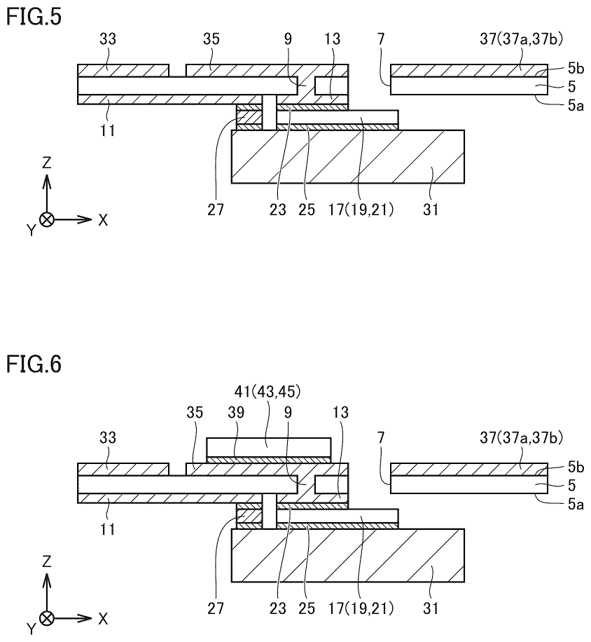

Subsequently, as shown in FIG. 5, first main electrode 19 of first power semiconductor device 17 and first interconnection layer 13 are bonded together by solder 23, and metal block 27 and first external main terminal 11 are bonded together by solder 23. Subsequently, as shown in FIG. 6, second interconnection layer 35 and second power semiconductor device 41 (on its back surface) are bonded together by solder 39.

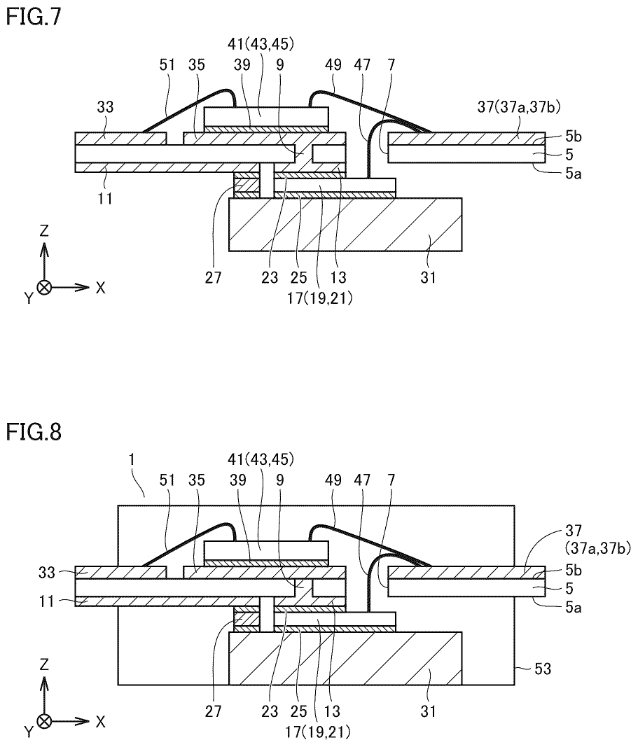

Subsequently, as shown in FIG. 7, first signal electrode 21 of first power semiconductor device 17 and first signal terminal 37a are electrically connected to each other by first bonding wire 47 through substrate opening 7. Second signal electrode 45 of second power semiconductor device 41 and second signal terminal 37b are electrically connected to each other by second bonding wire 49 so as to straddle substrate opening 7. Second main electrode 43 of second power semiconductor device 41 and second external main terminal 33 are electrically connected to each other by third bonding wire 51.

Subsequently, first power semiconductor device 17, second power semiconductor device 41, and the like mounted on substrate 5 are placed for example in a transfer molding die (not shown) and filled with sealing resin 53 (see FIG. 8). Thereafter, power module semiconductor package 1 sealed with sealing resin 53 is removed from the transfer molding die and thus completed as shown in FIG. 8.

For power module semiconductor package 1 described above, in the plan view seen from second major surface 5b of substrate 5 (i.e., the X-Y plane), first power semiconductor device 17 is provided with region 18 (an offset region) that does not overlap with second power semiconductor device 41 and substrate 5. Power module semiconductor package 1 can thus be miniaturized. This will be described in comparison with a power module semiconductor package according to a comparative example.

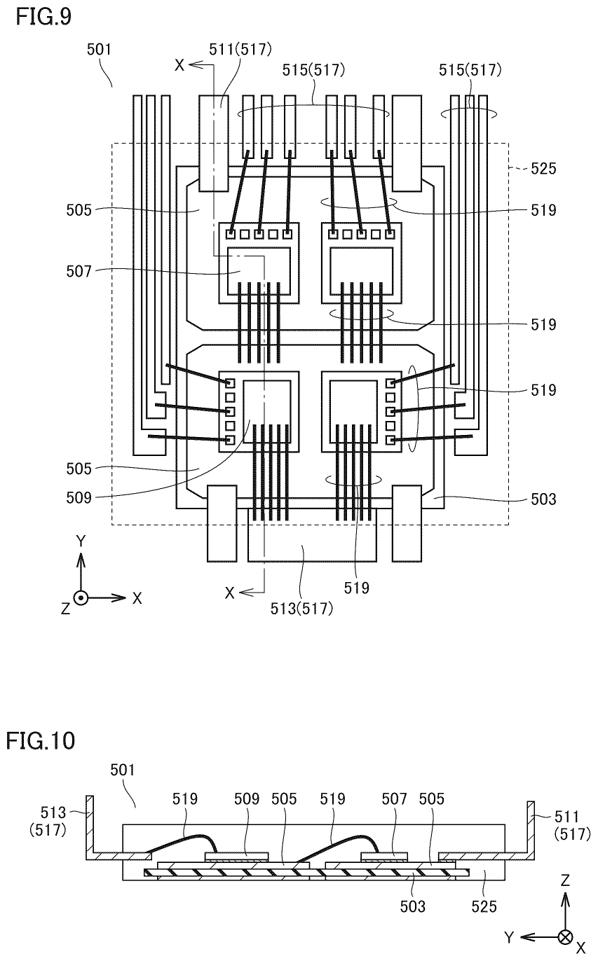

Initially, a power module semiconductor package according to a first comparative example will be described. As shown in FIGS. 9 and 10, in a power module semiconductor package 501 according to the first comparative example, two copper patterns 505 are formed on one major surface of an insulating substrate 503. A first power semiconductor device 507 is bonded to one copper pattern 505. A second power semiconductor device 509 is bonded to the other copper pattern 505.

A signal terminal 515 and first power semiconductor device 507 are electrically connected by a bonding wire 519. A first external main terminal 511 and first power semiconductor device 507 are electrically connected via one copper pattern 505. First power semiconductor device 507 and second power semiconductor device 509 are electrically connected by bonding wire 519 and the other copper pattern 505.

Signal terminal 515 and second power semiconductor device 509 are electrically connected by bonding wire 519. A second external main terminal 513 and second power semiconductor device 509 are electrically connected by bonding wire 519. Signal terminal 515, first external main terminal 511, and second external main terminal 513 are each formed of a lead frame 517.

In power module semiconductor package 501 according to the first comparative example, two copper patterns 505 are formed on one major surface of insulating substrate 503, and first power semiconductor device 507 is bonded to one copper pattern 505 and second power semiconductor device 509 is bonded to the other copper pattern 505. Furthermore, signal terminal 515, first external main terminal 511, and second external main terminal 513 formed of lead frame 517 are disposed so as to surround insulating substrate 503. Therefore, there is a limitation in miniaturizing power module semiconductor package 501.

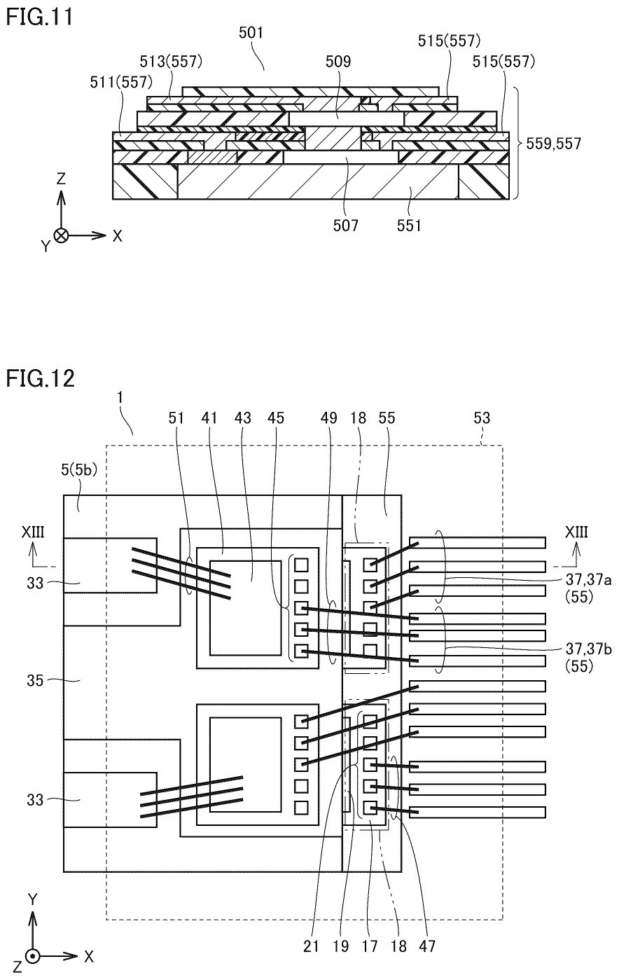

Power module semiconductor package 501 according to a second comparative example will be described. As shown in FIG. 11, an organic layer 559 is formed so as to surround a heat spreader 551. On a surface of heat spreader 551 and the like, a plurality of organic layers 559 and a plurality of plated interconnection layers 557 including vias are stacked in layers to form a structure of a stack of layers. In the structure of the stack of layers, first power semiconductor device 507 and second power semiconductor device 509 are disposed such that second power semiconductor device 509 overlies first power semiconductor device 507. At an outer peripheral portion of the structure of the stack of layers, plated interconnection layer 557 serving as first external main terminal 511, second external main terminal 513, and signal terminal 515 is exposed.

Power module semiconductor package 501 according to the second comparative example is extremely difficult to manufacture using existing manufacturing equipment using solder, bonding wire, or the like. Furthermore, a long period of time is consumed to form the plated interconnection layer, resulting in an increased manufacturing cost.

In contrast to the first comparative example and the second comparative example, power module semiconductor package 1 according to the first embodiment has first power semiconductor device 17 bonded to substrate 5 on first major surface 5a and second power semiconductor device 41 bonded to the substrate on second major surface 5b. Moreover, in the plan view seen from second major surface 5b of substrate 5 (i.e., the X-Y plane), first power semiconductor device 17 includes region 18 (an offset region) that does not overlap with second power semiconductor device 41 and substrate 5. First signal electrode 21 located in non-overlapping region 18 and signal terminal 37 are electrically connected by first bonding wire 47.

Thus, in power module semiconductor package 1 described above, first power semiconductor device 17 and second power semiconductor device 41 are stacked in a direction along the Z-axis, and first power semiconductor device 17 is provided with region 18 (an offset region) that does not overlap with second power semiconductor device 41 and substrate 5.

This allows power module semiconductor package 1 to be manufactured using existing manufacturing equipment using solder, bonding wire and/or the like while miniaturizing power module semiconductor package 1. As a result, power module semiconductor package 1 can be reduced in size and hence weight and can also be manufactured at a reduced cost.

### Second Embodiment

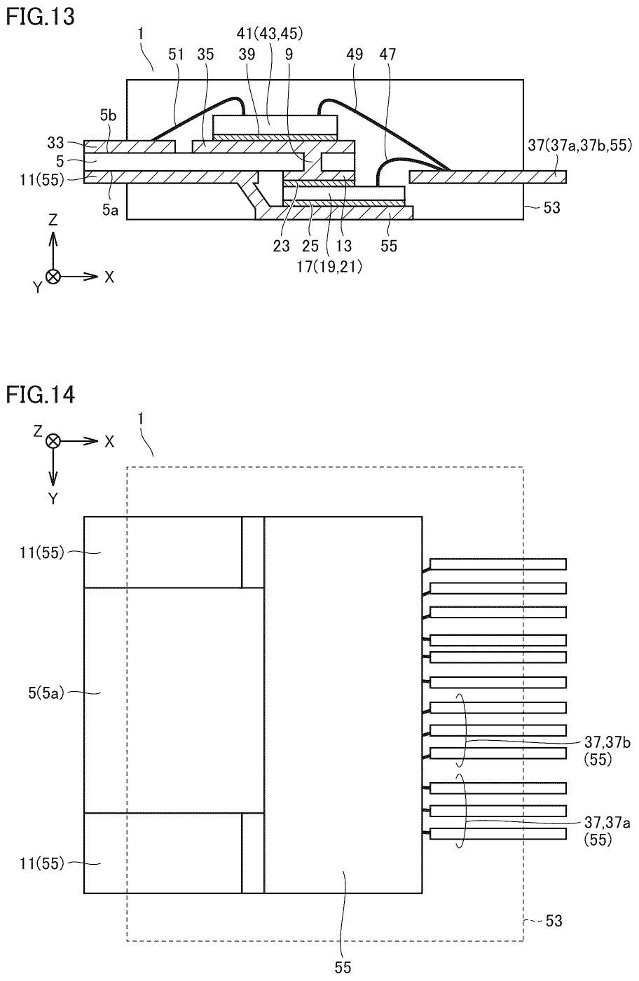

An example of a power module semiconductor package according to a second embodiment will now be described. As shown in FIGS. 12, 13, and 14, in power module semiconductor package 1 according to the second embodiment, a metal frame 55 is applied instead of heat spreader 31 and metal block 27 in power module semiconductor package 1 described above. Metal frame 55 has a portion (or a die pad) on which first power semiconductor device 17 is mounted, first external main terminal 11, and signal terminal 37 formed integrally.

In the plan view seen from second major surface 5b (i.e., the X-Y plane), first power semiconductor device 17 includes region 18 (an offset region) that does not overlap with second power semiconductor device 41 and signal terminal 37. Signal terminal 37 is disposed at a location at a distance from non-overlapping region 18 in a direction along the X-axis.

First signal electrode 21 of first power semiconductor device 17 located in non-overlapping region 18 and signal terminal 37 are electrically connected to each other by first bonding wire 47. Metal frame 55 has a surface exposed at a back surface of sealing resin 53 (or on a side thereof in a negative direction along the Z-axis).

The remainder in configuration is similar to that of power module semiconductor package 1 shown in FIGS. 1 to 3, and accordingly, identical members are identically denoted and will not be described repeatedly unless necessary.

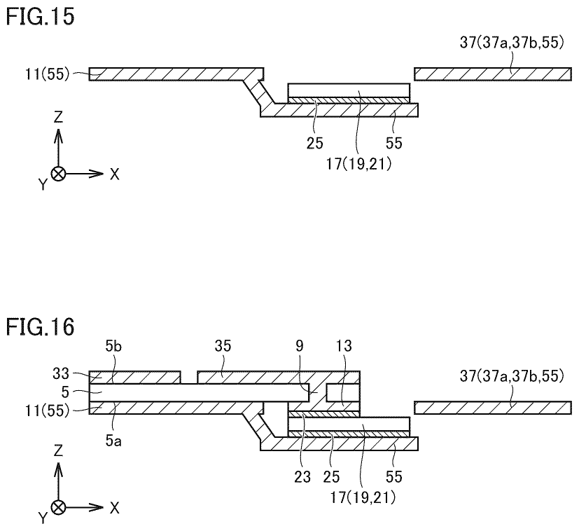

An example of a method for manufacturing power module semiconductor package 1 described above will now be described. Initially, metal frame 55 is prepared (see FIG. 15). Metal frame 55 has a portion (or a die pad) on which first power semiconductor device 17 is mounted, first external main terminal 11, and signal terminal 37 formed integrally. Subsequently, as shown in FIG. 15, the back surface of first power semiconductor device 17 and metal frame 55 are bonded together by solder 25.

Subsequently, substrate 5 having first major surface 5a and second major surface 5b opposite to each other is prepared (see FIG. 16). First interconnection layer 13 is formed in advance on first major surface Sa of substrate 5. Second interconnection layer 35 and second external main terminal 33 are formed on second major surface 5b of substrate 5. Subsequently, as shown in FIG. 16, first power semiconductor device 17 and first interconnection layer 13 of substrate 5 are bonded together by solder 23. First external main terminal 11 of metal frame 55 is bonded to first major surface 5a of substrate 5.

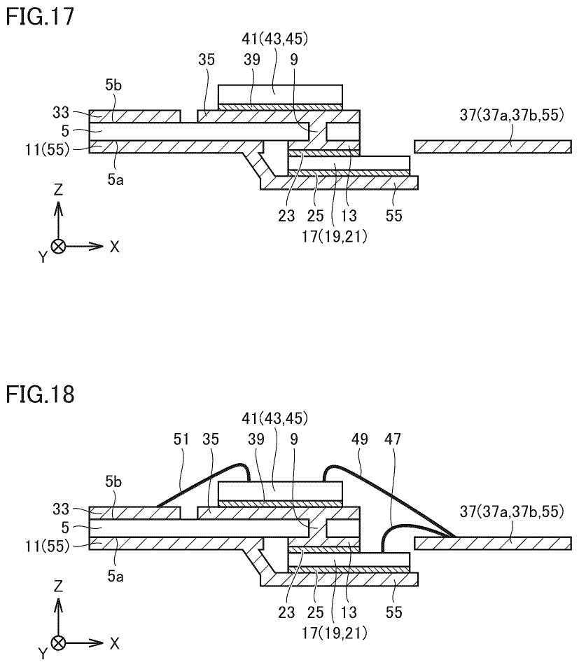

Subsequently, as shown in FIG. 17, second interconnection layer 35 of substrate 5 and second power semiconductor device 41 (on its back surface) are bonded together by solder 39. Subsequently, as shown in FIG. 18, first signal electrode 21 of first power semiconductor device 17 and first signal terminal 37a are electrically connected to each other by first bonding wire 47. Second signal electrode 45 of second power semiconductor device 41 and second signal terminal 37b are electrically connected to each other by second bonding wire 49. Second main electrode 43 of second power semiconductor device 41 and second external main terminal 33 are electrically connected to each other by third bonding wire 51.

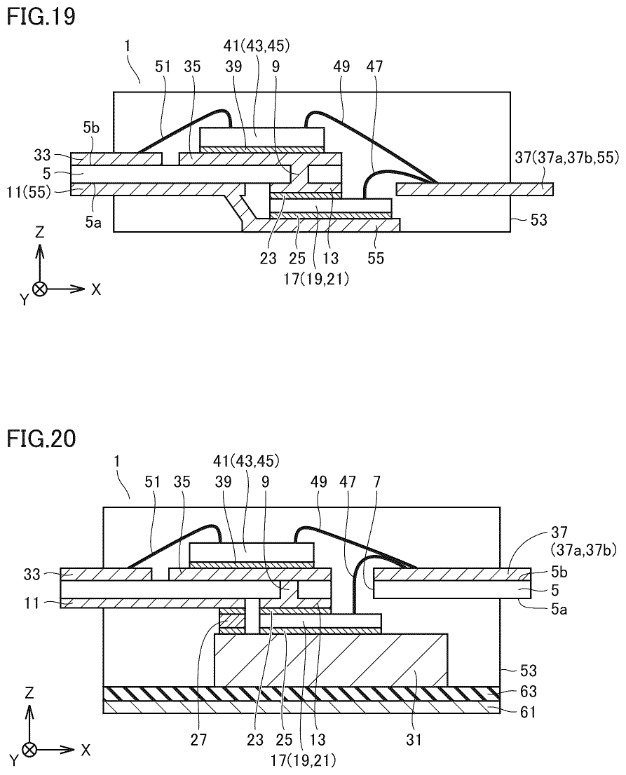

Subsequently, first power semiconductor device 17, second power semiconductor device 41, and the like mounted on substrate 5 are placed for example in a transfer molding die (not shown) and filled with sealing resin 53 (see FIG. 19). Thereafter, power module semiconductor package 1 sealed with sealing resin 53 is removed from the transfer molding die and thus completed as shown in FIG. 19.

Power module semiconductor package 1 according to the second embodiment has first power semiconductor device 17 bonded to substrate 5 on first major surface 5a and second power semiconductor device 41 bonded to the substrate on second major surface 5b. Moreover, in the plan view seen from second major surface 5b of substrate 5 (i.e., the X-Y plane), first power semiconductor device 17 includes region 18 (an offset region) that does not overlap with second power semiconductor device 41 and signal terminal 37. First signal electrode 21 located in non-overlapping region 18 and signal terminal 37 are electrically connected to each other by first bonding wire 47.

This allows power module semiconductor package 1 to be manufactured using existing manufacturing equipment using solder, bonding wire and/or the like while miniaturizing power module semiconductor package 1. As a result, power module semiconductor package 1 can be reduced in size and hence weight and can also be manufactured at a reduced cost.

Furthermore, for power module semiconductor package 1 described above, substrate 5 without substrate opening 7 is used. Furthermore, first external main terminal 11 and signal terminal 37 are formed from metal frame 55. This can contribute to a reduction in a production cost including a cost required for substrate 5. Furthermore, it is unnecessary to pass first bonding wire 47 through a substrate opening, which can make wire bonding easier.

### Third Embodiment

An example of a power module semiconductor package according to a third embodiment will be described. As shown in FIG. 20, power module semiconductor package 1 according to the third embodiment has a metal plate 61 joined to a surface of heat spreader 31 on a side opposite to a side on which first power semiconductor device 17 is bonded, with an insulating material 63 interposed therebetween. Metal plate 61 is exposed from sealing resin 53.

As insulating material 63, an inorganic filler such as alumina, boron nitride, silica, or aluminum nitride having excellent thermal conductivity may be applied in order to coestablish insulation and heat dissipation. Further, as insulating material 63, a thermally conductive sheet having thermosetting resin mixed therein may be applied. The remainder in configuration is similar to that of power module semiconductor package 1 shown in FIGS. 1 to 3, and accordingly, identical members are identically denoted and will not be described repeatedly unless necessary.

Power module semiconductor package 1 described above has an effect such as miniaturization and the like described in the first embodiment, and in addition, the following effect.

Insulating material 63 is interposed between heat spreader 31 and metal plate 61. This ensures insulation between a cooler such as a heat sink attached to metal plate 61 for example and first power semiconductor device 17 or the like. As a result, the cooler can be more firmly secured to metal plate 61 by using, for example, a metal bonding material such as solder.

### Fourth Embodiment

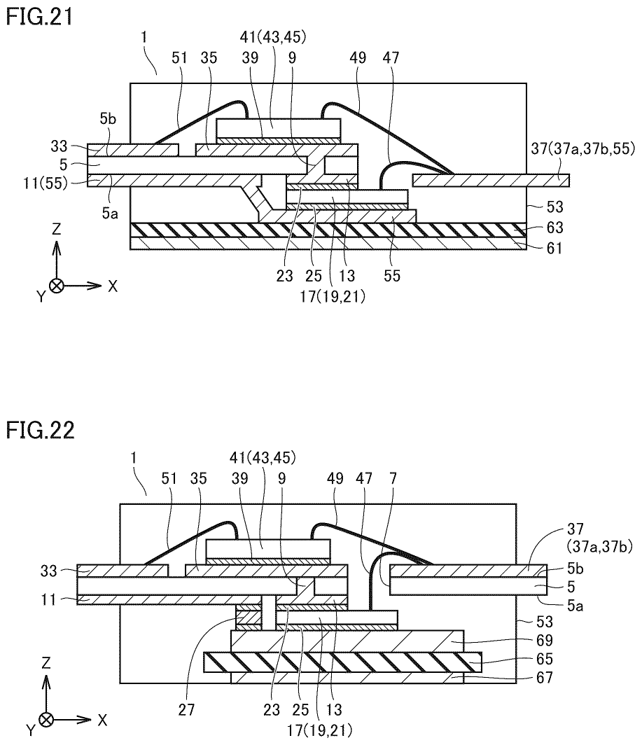

An example of a power module semiconductor package according to a fourth embodiment will be described. As shown in FIG. 21, power module semiconductor package 1 according to the fourth embodiment has metal plate 61 joined to a surface of metal frame 55 on a side opposite to a side on which first power semiconductor device 17 is bonded, with insulating material 63 interposed therebetween. Metal plate 61 is exposed from sealing resin 53.

As insulating material 63, an inorganic filler such as alumina, boron nitride, silica or aluminum nitride, or a thermally conductive sheet having thermosetting resin mixed therein is applied in order to coestablish insulation and heat dissipation. The remainder in configuration is similar to that of power module semiconductor package 1 shown in FIGS. 12 to 14, and accordingly, identical members are identically denoted and will not be described repeatedly unless necessary.

Power module semiconductor package 1 described above has an effect such as miniaturization and the like described in the second embodiment, and in addition, the following effect.

Insulating material 63 is interposed between metal frame 55 and metal plate 61. This ensures insulation between a cooler (a heat sink) attached to metal plate 61 for example and first power semiconductor device 17 or the like. As a result, the cooler can be more firmly secured to metal plate 61 by using, for example, a metal bonding material such as solder.

### Fifth Embodiment

An example of a power module semiconductor package according to a fifth embodiment will be described. As shown in FIG. 22, power module semiconductor package 1 according to the fifth embodiment comprises an insulating substrate 65. A first copper pattern 67 is bonded to one surface (or a lower surface) of insulating substrate 65. A second copper pattern 69 is bonded to the other surface (or an upper surface) of insulating substrate 65.

Second copper pattern 69 and first interconnection layer 13 are bonded to each other by solder 23. Further, second copper pattern 69 and metal block 27 are bonded to each other by solder 23. First copper pattern 67 is exposed from a surface of scaling resin 53. The remainder in configuration is similar to that of power module semiconductor package 1 shown in FIGS. 1 to 3, and accordingly, identical members are identically denoted and will not be described repeatedly unless necessary.

Power module semiconductor package 1 described above has an effect such as miniaturization and the like described in the first embodiment, and in addition, the following effect.

Insulating substrate 65 is interposed between first copper pattern 67 and second copper pattern 69. This ensures insulation between a cooler (a heat sink) attached to first copper pattern 67 for example and first power semiconductor device 17 or the like. As a result, the cooler can be more firmly secured to first copper pattern 67 by using, for example, a metal bonding material such as solder.

### Sixth Embodiment

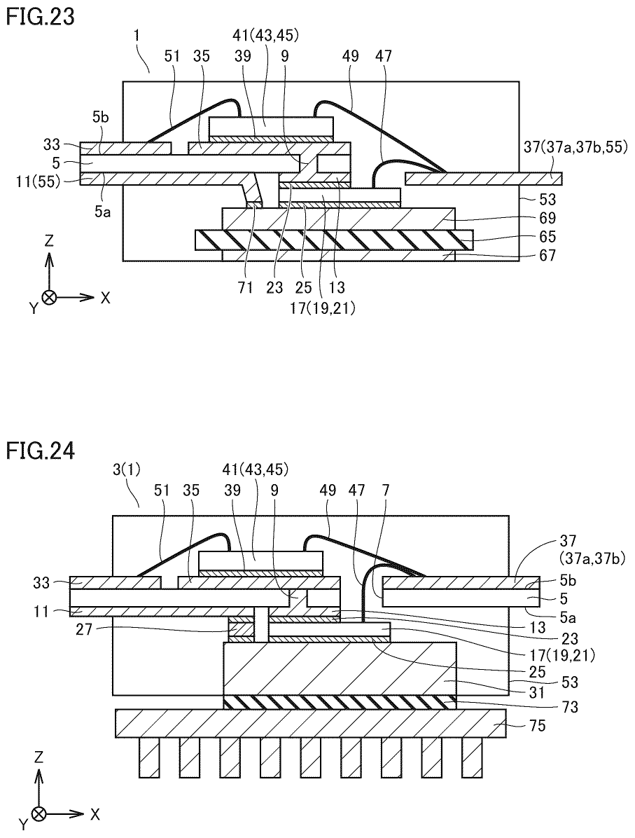

An example of a power module semiconductor package according to a sixth embodiment will be described. As shown in FIG. 23, power module semiconductor package 1 according to the sixth embodiment comprises insulating substrate 65. First copper pattern 67 is bonded to one surface (or the lower surface) of insulating substrate 65. Second copper pattern 69 is bonded to the other surface (or the upper surface) of insulating substrate 65.

Second copper pattern 69 and first interconnection layer 13 are bonded to each other by solder 23. Furthermore, second copper pattern 69 and first external main terminal 11 are bonded to each other by solder 71. First copper pattern 67 is exposed from a surface of scaling resin 53. The remainder in configuration is similar to that of power module semiconductor package 1 shown in FIGS. 12 to 14, and accordingly, identical members are identically denoted and will not be described repeatedly unless necessary.

Power module semiconductor package 1 described above has an effect such as miniaturization and the like described in the second embodiment, and in addition, the following effect.

Insulating substrate 65 is interposed between first copper pattern 67 and second copper pattern 69. This ensures insulation between a cooler (a heat sink) attached to first copper pattern 67 for example and first power semiconductor device 17 or the like. As a result, the cooler can be more firmly secured to first copper pattern 67 by using, for example, a metal bonding material such as solder.

### Seventh Embodiment

A semiconductor apparatus as power conversion equipment, that is power module semiconductor package 1 with a heat sink attached thereto, will be described.

### First Example

As shown in FIG. 24, a semiconductor apparatus 3 according to a first example has a heat sink 75 joined to a surface (a lower surface) of heat spreader 31 exposed from sealing resin 53, with an insulating material 73 interposed therebetween. The remainder in configuration is similar to that of power module semiconductor package 1 shown in FIGS. 1 to 3, and accordingly, identical members are identically denoted and will not be described repeatedly unless necessary.

Semiconductor apparatus 3 according to the first example described above has an effect such as miniaturization and the like described in the first embodiment, and in addition, the following effect.

Semiconductor apparatus 3 according to the first example has heat sink 75 attached to a power module semiconductor package. The power module semiconductor package generates heat, which is transferred to heat sink 75 via insulating material 73. As a result, semiconductor apparatus 3 can be further heat dissipative.

### Second Example

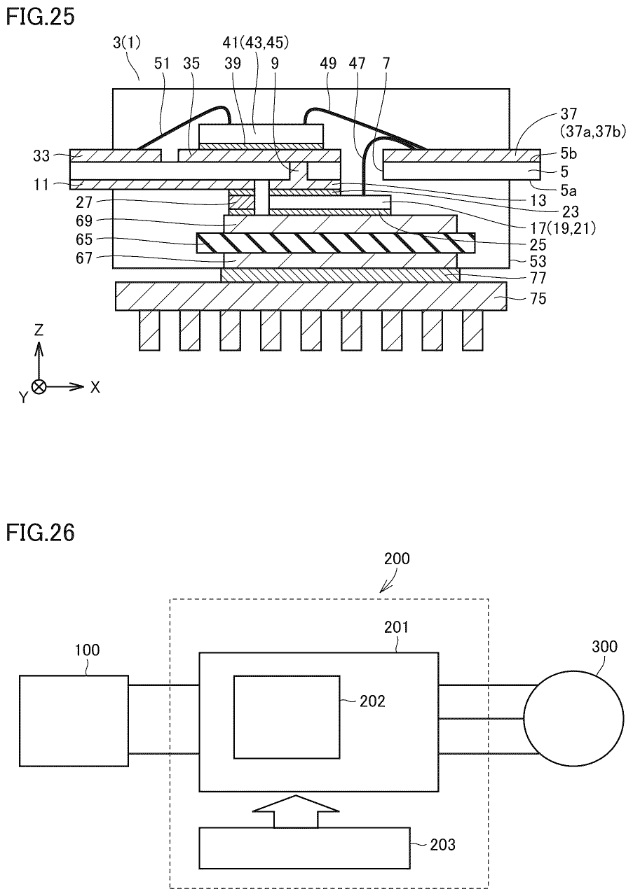

As shown in FIG. 25, semiconductor apparatus 3 according to a second example comprises insulating substrate 65, and first copper pattern 67 is bonded to one surface (or a lower surface) of insulating substrate 65 and second copper pattern 69 is bonded to the other surface (or an upper surface) of the insulating substrate. Heat sink 75 is bonded by a conductive metal bonding material 77 to first copper pattern 67 exposed from a surface of sealing resin 53.

The remainder in configuration is similar to that of power module semiconductor package 1 shown in FIG. 22, and accordingly, identical members are identically denoted and will not be described repeatedly unless necessary.

Semiconductor apparatus 3 according to the second example described above has an effect such as miniaturization and the like described in the fifth embodiment, and in addition, the following effect.

Semiconductor apparatus 3 according to the second example has insulating substrate 65 interposed between first copper pattern 67 and second copper pattern 69. This ensures insulation between heat sink 75 attached to first copper pattern 67 and first power semiconductor device 17 or the like. This allows heat sink 75 to be bonded to first copper pattern 67 by conductive metal bonding material 77, and heat generated in power module semiconductor package 1 is efficiently transferred to heat sink 75 via conductive metal bonding material 77. As a result, semiconductor apparatus 3 can be further heat dissipative.

### Eighth Embodiment

Hereinafter will be described a semiconductor apparatus as power conversion equipment in which a cooler such as a heat sink is attached to power module semiconductor package 1 described in the first to sixth embodiments, or semiconductor apparatus 3 as power conversion equipment that is described in the seventh embodiment. Although the present disclosure is not limited to a specific semiconductor apparatus, hereinafter a case in which the present disclosure is applied to a three-phase inverter will be described below as an eighth embodiment.

FIG. 26 is a block diagram illustrating a configuration of a power conversion system to which the semiconductor apparatus according to the present embodiment is applied. The power conversion system illustrated in FIG. 26 is composed of a power supply 100, a semiconductor apparatus 200, and a load 300. Power supply 100 is a direct-current power supply and supplies direct-current power to semiconductor apparatus 200. Power supply 100 can be configured by a variety of types, and can be configured for example by a direct-current system, a solar battery, or a storage battery. Furthermore, power supply 100 may be configured by a rectifier circuit or an AC/DC converter connected to an alternate-current system. Furthermore, power supply 100 may be configured by a DC/DC converter that receives direct-current power output from a direct-current system and converts the received power to predetermined power.

Semiconductor apparatus 200 is a three-phase inverter connected between power supply 100 and load 300, and receives direct-current power from power supply 100, converts the received direct-current power to alternate-current power, and supplies the alternate-current power to load 300. As shown in FIG. 26, semiconductor apparatus 200 comprises a main conversion circuit 201 to convert direct-current power to alternate-current power and output the alternate-current power, and a control circuit 203 to output a control signal to main conversion circuit 201 to control main conversion circuit 201.

Load 300 is a three-phase electric motor driven by alternate-current power received from semiconductor apparatus 200. Note that load 300 is not limited to a specific application, and it is an electric motor mounted on a variety of types of electric devices and is used for example as an electric motor for a hybrid vehicle, an electric vehicle, a railroad vehicle, an elevator, or an air-conditioning device.

Hereinafter, semiconductor apparatus 200 will be described in detail. Main conversion circuit 201 includes a switching element and a freewheeling diode (not shown). As the switching element is switched, direct-current power received from power supply 100 is converted to alternate-current power and thus supplied to load 300. While there are a variety of types of specific circuit configurations for main conversion circuit 201, main conversion circuit 201 according to the present embodiment is a two-level three-phase full-bridge circuit and can be composed of six switching elements and six freewheeling diodes anti-parallel to the respective switching elements.

At least one of the switching elements and freewheeling diodes of main conversion circuit 201 is a switching element or a freewheeling diode included in a semiconductor module 202 corresponding to power module semiconductor package 1 according to at least one of the first to seventh embodiments described above. The six switching elements have every two switching elements connected in series to form upper and lower arms, and the upper and lower arms configure the full bridge circuit's phases (a U phase, a V phase and a W phase). The upper and lower arms' output terminals, that is, main conversion circuit 201's three output terminals, are connected to load 300.

Further, main conversion circuit 201 includes a drive circuit (not shown) to drive each switching element, and the main conversion circuit may have the drive circuit incorporated in semiconductor module 202 or may include the drive circuit separately from semiconductor module 202. The drive circuit generates a drive signal to drive the switching elements of main conversion circuit 201 and supplies the drive signal to a control electrode of each switching element of main conversion circuit 201. Specifically, in response to a control signal from control circuit 203 described later, a drive signal to turn on a switching element and a drive signal to turn off a switching element are output to the control electrode of each switching element. When the switching element is held on, the drive signal is a voltage signal equal to or higher than the threshold voltage of the switching element (an ON signal), whereas when the switching element is held off, the drive signal is a voltage signal equal to or lower than the threshold voltage of the switching element (an OFF signal).

Control circuit 203 controls the switching elements of main conversion circuit 201 so that load 300 receives desired power. Specifically, it calculates a time for which each switching element of main conversion circuit 201 should be turned on (i.e., an ON time) based on the power to be supplied to load 300. For example, it can control main conversion circuit 201 by PWM control by which a switching element has an ON time modulated in accordance with voltage to be output. It outputs a control command (a control signal) to the drive circuit included in main conversion circuit 201 so that the ON signal is output to a switching element to be turned on at each point in time and the OFF signal is output to a switching element to be turned off at each point in time. In response to the control signal, the drive circuit outputs the ON signal or the OFF signal as a drive signal to the control electrode of each switching element.

In semiconductor apparatus 200 according to the present embodiment, power module semiconductor package 1 according to the first to seventh embodiments is applied as semiconductor module 202 configuring main conversion circuit 201, and miniaturization, weight reduction, and the like can thus be achieved.

While in the present embodiment, an example in which the present invention is applied to a two-level three-phase inverter has been described, the present disclosure is not limited thereto, and is applicable to a variety of types of semiconductor apparatuses. Although the present embodiment has been described for a two-level semiconductor apparatus, it may be a three-level or multi-level semiconductor apparatus, and the present disclosure may be applied to a single-phase inverter when electric power is supplied to a single-phase load. The present disclosure is also applicable to a DC/DC converter or an AC/DC converter when power is supplied to a direct-current load or the like.

Furthermore, a semiconductor apparatus with the present disclosure applied thereto is not limited to a case in which a load is an electric motor, as described above, and may be used as a power supply device for an electric spark machine, a laser material processing machine, an induction heating cooker, or a contactless power feeding system, and furthermore, can also be used as a power conditioner for a photovoltaic power generation system, a power storage system, or the like.

The power module semiconductor packages and the like described in the embodiments can be combined together variously as required.

The presently disclosed embodiments are illustrative and not restrictive. The present disclosure is indicated by the terms of the claims, rather than the scope described above, and is intended to encompass any modifications within the meaning and scope equivalent to the terms of the claims.

### INDUSTRIAL APPLICABILITY

The present disclosure is effectively utilized for a power module semiconductor package having a power semiconductor device mounted therein, and a semiconductor apparatus comprising the power module semiconductor package and a cooler.

### REFERENCE SIGNS LIST

1 power module semiconductor package, 3 semiconductor apparatus, 5 substrate, 5a first major surface, 5b second major surface, 7 substrate opening, 9 via, 11 first external main terminal, 13 first interconnection layer, 15 solder, 17 first power semiconductor device, 18 non-overlapping region, 19 first main electrode, 21 first signal electrode, 23, 25 solder, 27 metal block, 29 solder, 31 heat spreader, 33 second external main terminal, 35 second interconnection layer, 37 signal terminal, 37a first signal terminal, 37b second signal terminal, 39 solder, 41 second power semiconductor device, 43 second main electrode, 45 second signal electrode, 47 first bonding wire, 49 second bonding wire, 51 third bonding wire, 53 sealing resin, 55 metal frame, 61 metal plate, 63 insulating material, 65 insulating substrate, 67 first copper pattern, 69 second copper pattern, 71 solder, 73 insulating material, 75 heat sink, 77 conductive metal bonding material, 100 power supply, 200 semiconductor apparatus, 201 main conversion circuit, 202 semiconductor module, 203 control circuit, 300 load.

1. A power module semiconductor package comprising:
a substrate having a first major surface and a second major surface opposite to each other;
a first power semiconductor device mounted on the substrate at the first major surface;
a second power semiconductor device mounted on the substrate at the second major surface;
an external main terminal including a first external main terminal electrically connected to the first power semiconductor device and a second external main terminal electrically connected to the second power semiconductor device;
a signal terminal including a first signal terminal electrically connected to the first power semiconductor device and a second signal terminal electrically connected to the second power semiconductor device; and
a sealing resin sealing the first power semiconductor device and the second power semiconductor device in such a manner that the external main terminal and the signal terminal protrude,
the external main terminal being disposed on a side opposite to a side on which the signal terminal is disposed with respect to the first power semiconductor device and the second power semiconductor device,
the first power semiconductor device and the second power semiconductor device being electrically connected to each other via a via penetrating the substrate,
in a plan view seen from the second major surface of the substrate, the first power semiconductor device including a region that does not overlap with the second power semiconductor device and the substrate,
the first power semiconductor device and the first signal terminal being electrically connected by a bonding wire that interconnects the non-overlapping region of the first power semiconductor device and the first signal terminal.

2. The power module semiconductor package according to claim 1, wherein
the substrate has a substrate opening penetrating therethrough, and
in the plan view seen from the second major surface of the substrate, the non-overlapping region is located at the substrate opening.

3. The power module semiconductor package according to claim 2, further comprising a heat spreader that is bonded on a side opposite, with respect to the first power semiconductor device, to a side on which the substrate is bonded, and that is electrically connected to the first external main terminal and the first power semiconductor device.

4. The power module semiconductor package according to claim 3, wherein
a first metal plate is joined on a side opposite, with respect to the heat spreader, to a side on which the first power semiconductor device is bonded, with a first insulating material interposed therebetween, and
the first metal plate is exposed from the sealing resin.

5. The power module semiconductor package according to claim 1, further comprising a metal frame including the first external main terminal and the signal terminal, wherein
in the plan view seen from the second major surface of the substrate, the signal terminal is disposed at a distance from the non-overlapping region.

6. The power module semiconductor package according to claim 5, wherein the metal frame is bonded on a side opposite, with respect to the first power semiconductor device, to a side on which the substrate is bonded.

7. The power module semiconductor package according to claim 5, wherein
a second metal plate is joined on a side opposite, with respect to the metal frame, to a side on which the first power semiconductor device is bonded, with a second insulating material interposed therebetween, and
the second metal plate is exposed from the sealing resin.

8. The power module semiconductor package according to claim 1, further comprising an insulating substrate joined on a side opposite, with respect to the first power semiconductor device, to a side on which the substrate is bonded, wherein
the insulating substrate includes
an insulating plate having a third major surface and a fourth major surface opposite to each other,
a first conductive pattern formed on the third major surface of the insulating plate, and
a second conductive pattern formed on the fourth major surface of the insulating plate,
the first conductive pattern is exposed from the sealing resin, and
the first power semiconductor device and the first external main terminal are bonded to the second conductive pattern.

9. (canceled)

10. The power module semiconductor package according to claim 5, further comprising an insulating substrate joined on a side opposite, with respect to the first power semiconductor device, to a side on which the substrate is bonded, wherein
the insulating substrate includes
an insulating plate having a third major surface and a fourth major surface opposite to each other,
a first conductive pattern formed on the third major surface of the insulating plate, and
a second conductive pattern formed on the fourth major surface of the insulating plate,
the first conductive pattern is exposed from the sealing resin, and
the first power semiconductor device and the first external main terminal are bonded to the second conductive pattern.

11. A semiconductor apparatus having the power module semiconductor package according to claim 1, comprising:
a cooler attached to the power module semiconductor package;
a main conversion circuit to receive power, convert the received power, and output the converted power; and
a control circuit to output a control signal to the main conversion circuit to control the main conversion circuit.
